(19) United States
(12) Patent Application Publication
(10) Pub. No.: US 2026/0073089 A1
(43) Pub. Date: Mar. 12, 2026

(54) OPTIMIZATION LAYOUT METHOD FOR PLP LIGHTNING PROTECTION IN PHOTOVOLTAIC POWER STATIONS

(71) Applicant: Kunming University of Science and Technology, Kunming (CN)

(72) Inventors: Hongchun SHU, Kunming (CN); Yutao TANG, Kunming (CN); Weijie LOU, Kunming (CN); Yiming HAN, Kunming (CN); Yue DAI, Kunming (CN); Haoming LIU, Kunming (CN); Jun DONG, Kunming (CN)

(73) Assignee: Kunming University of Science and Technology, Kunming (CN)

(21) Appl. No.: 19/026,907

(22) Filed: Jan. 17, 2025

(30) Foreign Application Priority Data
Sep. 11, 2024 (CN) 202411269032.1

(51) Int. Cl. G06F 30/18; H05F 3/00

(52) U.S. Cl. CPC G06F 30/18; H05F 3/00

(57) ABSTRACT

An optimization layout method for PLP lightning protection in a photovoltaic power station includes: determining the size of the protected area required by the photovoltaic power station; determining the height hₓ of the protected electrical equipment; determining the protection distance rₓ of a single PLP device at the protected height hₓ; determining the external protection range and the internal protection range when multiple PLP devices jointly protect; calculating the optimal PLP layout scheme by combining the respective maximum horizontal distances to achieve effective lightning protection for the photovoltaic power station. The method of the present invention can be widely applied to the optimization layout of lightning protection in photovoltaic power stations.

### CROSS-REFERENCE TO THE RELATED APPLICATIONS

This application is based upon and claims priority to Chinese Patent Application No. 202411269032.1, filed on Sep. 11, 2024, the entire contents of which are incorporated herein by reference.

### TECHNICAL FIELD

The present invention belongs to the field of lightning protection for power systems, and specifically relates to an optimization layout method for PLP lightning protection in photovoltaic power stations.

### BACKGROUND

Photovoltaic power stations are widely distributed with a large area. The main components are all installed outdoors and are scattered. The photovoltaic modules, secondary equipment and communication equipment in the station are all at risk of being struck by direct and indirect lightning. Lightning strikes pose a huge threat to the safe and stable operation of photovoltaic power stations as well as to the safety of equipment and personnel. The principle of traditional lightning rods and air terminals is to utilize the phenomenon of corona discharge at the tip to attract the lightning cloud charges in the atmosphere to the lightning rod and discharge in advance, and then conduct the lightning current to the ground through its own grounding conductor to avoid the protected object being struck directly by lightning. Although this method is simple, it has many drawbacks. For example, the large current flowing into the ground will cause the ground potential to rise, resulting in hazards such as equipment back-flashover overvoltage, induced lightning overvoltage and personal electric shock.

In recent years, the PLP (Passive Plasma Lightning Protector) passive plasma lightning rejection device has been widely used due to its unique “lightning elimination” principle and the advantage of not needing to attract lightning to the ground. The new lightning protection device—Plasma Lightning Protector (PLP) has a good effect in lightning protection. With the “quasi-tip effect”, its own electric field strength under the thundercloud is two orders of magnitude higher than that of the protected object, thus attracting and gathering the thundercloud charges and making the protected target in a safe position with a relatively low electric field. It also adopts the induction array lightning-resistant needles and the dielectric barrier strong ionization composite discharge device to achieve passive strong ionization by utilizing the electric field of the thundercloud. The strong ionization discharge device generates and emits high-concentration plasma in both directions between the cloud and the ground, and efficiently neutralizes the thundercloud charges attracted and gathered by the lightning-resistant needles, solving the fatal problem that the self-shielding effect of the electric field of the traditional lightning eliminator array needles suppresses the increase of the divergence current and is easily broken down by lightning. Under the attraction of the electric field of the thundercloud and the ground reverse polarity electric field induced by it, the positive (negative) ions in the plasma drift upward to neutralize the negative (positive) ions of the thundercloud above the needle tip, and the negative (positive) ions in the plasma drift downward to neutralize the positive (negative) ions induced by the thundercloud below the needle tip. It continuously attracts and gathers and conducts bidirectional neutralization of the thundercloud negative (positive) ions around the discharge device body and its induced positive (negative) ions, making the equivalent capacitance plates between the thundercloud and the ground leak electricity efficiently and become “bad capacitors” that cannot be charged to the electric field strength required for the formation of a lightning leader and the subsequent breakdown discharge.

However, the installation and optimal layout of PLP devices cannot simply copy the optimization of the layout of lightning rods. It is necessary to consider the protection range of a single PLP and the protection range of multiple PLP devices working together, and also to select according to economy in combination with the protection range of PLP. At present, there is still a lack of an optimization layout method for PLP devices in photovoltaic power stations.

### SUMMARY

To solve the above technical problems, the present invention provides an optimization layout method for PLP lightning protection in photovoltaic power stations, which includes:
step1. measuring the range that needs to be protected in the photovoltaic power station site;
step2. determining the height hₓ of the protected object;
step3. calculating the protection distance rₓ of a single PLP device, rₓ=10(h−hₓ), where the protection angle of the PLP device is 84°-86° and the protection radius R=10h where h is the installation height of the PLP device.
step4. when a single PLP device cannot protect the entire area of the photovoltaic power station site, increasing to two PLP devices and calculating the lowest protection height h₀ in the middle of the two PLP devices.

$${h}_{0} = h - \frac{D}{40 p}$$

where the maximum distance Dₘₐₓ between two PLP devices with the same height can be determined when h₀=hₓ, p is the correction coefficient considering the influence of the installation height of the PLP device, and when h≤30 m, p=1; when 30 m<h≤120 m, p=5.5/\sqrt{h};
step5. when two PLP devices still cannot meet the protection requirements, continue to increase to three PLP devices. when three PLP devices form a triangle, the protection range on the outside is determined according to the method for two PLP devices. for the protection range on the inside, based on the height hₓ of the protected object, calculating the lowest protection height h₀ of each pair of adjacent PLP devices respectively. as long as h₀≥hₓ, the protection range on the inside can meet the requirements.
step6. if the number of PLP devices continues to increase, divide the photovoltaic power station site to be protected into two or more triangles, and then calculate according to the method for three PLP devices. referring to step3-step5 to calculate the protection range of each triangle, and then comprehensively obtain the protection range of in PLP devices (n>3) until the requirements for the protection range of the photovoltaic power station site to be protected are met.

Furthermore, when determining the height hₓ of the protected object in step2, the longitudinal and transverse dimensions and the creepage distance of the outdoor high-voltage distribution equipment should be taken into consideration. If the heights hₓ of the protected equipment are not consistent and are not unique, the maximum hₓ should be taken. Generally speaking, the protected height of photovoltaic panels is taken as 5 meters, and the protected height of wind turbines is taken as 110 meters.

Furthermore, when calculating the protection range rₓ at the height hₓ of the protected object in step3, try to make the installation height h of the PLP as low as possible and less than 30 m. If the installation height is too high, more guy wires will be needed for fixing the PLP device.

Furthermore, when determining the maximum distance Dₘₐₓ between two PLP devices with the same height in step4,

$$\frac{D}{h} \leq 5$$

between the two devices.

Furthermore, if the protected range is slightly smaller than the protection area, the method of increasing the installation height of local PLP devices can be adopted to enlarge the protection range and form the optimal combination of PLP groups with different heights.

Furthermore, when installing three or more PLP devices, a method of leaving a 10% margin can be used to avoid calculating whether the local edge areas are protected or not.

### Beneficial Effects

1. It is determined that the limiting distance among multiple PLP devices can maximize the protection range and has good economic efficiency. Compared with traditional configuration schemes, it can achieve both the technical and economic aspects of PLP installation.
2. When multiple PLP devices work together, the protection range of the intermediate area is enhanced. This method conducts qualitative calculations to expand the protection range and makes up for the deficiency in the original calculation of the PLP protection range which was only calculated based on the protection range of a single PLP device.
3. For the optimization layout of any complex terrain, it can be divided into multiple triangular areas for analysis and calculation of the protection range. This method is applicable to any irregular area.

### BRIEF DESCRIPTION OF THE DRAWINGS

In order to illustrate the technical solutions in the embodiments of the present invention or in the prior art more clearly, the following will briefly introduce the accompanying drawings that need to be used in the description of the embodiments or the prior art. Obviously, the accompanying drawings in the following description are just some embodiments of the present invention. For those of ordinary skill in the art, without performing creative work, other accompanying FIGS can also be obtained based on these accompanying FIGS.

FIG. 1 is a diagram of the protection range of two PLP devices;

FIG. 2 is a schematic diagram of the first part of the protection range of the PLP device in Embodiment 1;

FIG. 3 is a schematic diagram of the second part of the protection range of the PLP device in Embodiment 1;

FIG. 4 is a schematic diagram of the protection range of the PLP device in Embodiment 2;

FIG. 5 is a schematic diagram of the protected area in Embodiment 3;

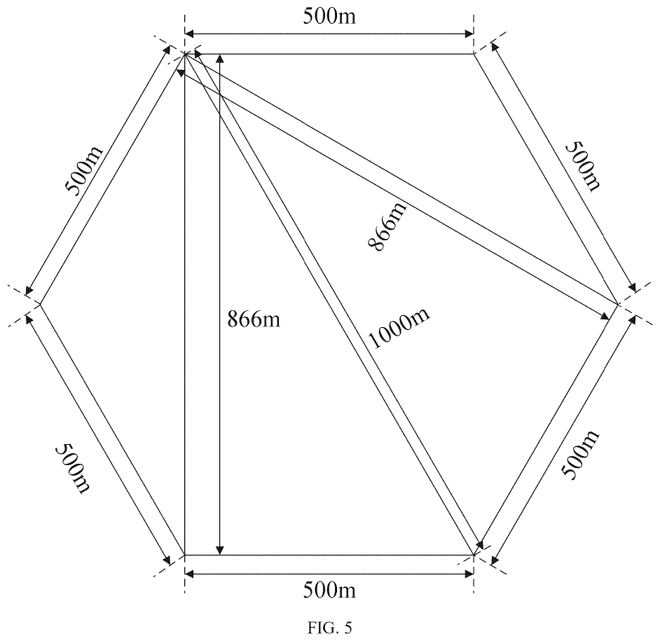

FIG. 6 is a schematic diagram of the first part of the protection range of the PLP device in Embodiment 3;

FIG. 7 is a schematic diagram of the second part of the protection range of the PLP device in Embodiment 3.

### DETAILED DESCRIPTION OF THE EMBODIMENTS

The following will clearly and completely describe the technical solutions in the embodiments of the present invention in combination with the accompanying drawings in the embodiments of the present invention. Obviously, the described embodiments are only a part of the embodiments of the present invention, rather than all of them. Based on the embodiments in the present invention, all other embodiments obtained by those of ordinary skill in the art without creative work fall within the protection scope of the present invention.

### Embodiment 1

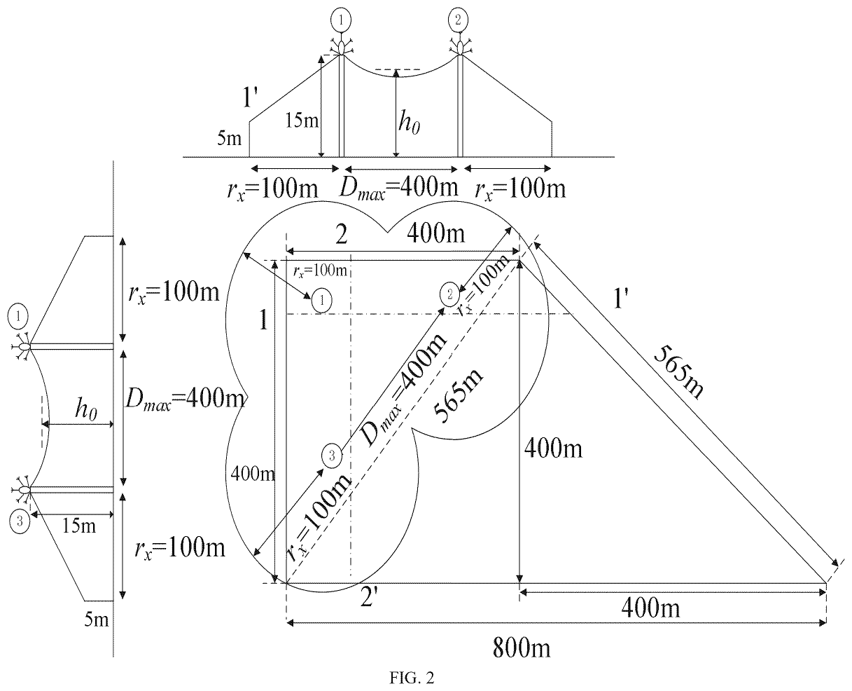

Referring to the above method, in this embodiment, a photovoltaic power station site in a right trapezoidal area with an upper base of 400 meters, a lower base of 800 meters and a height of 400 meters is protected. First, the trapezoidal area is divided into two triangular areas, and PLP lightning protection devices are arranged in the first triangular area, that is, the upper left triangular area, as shown in FIG. 2.

Regarding the 1-1′ section:
step1. determining the protected height of the photovoltaic panels;

$${h}_{x} = 5 m \qquad ( 1 )$$

step2. giving the initial installation height of PLP as 15 m;
the external protection radius of the PLP device can be determined by the following formula (2):

$${r}_{x} = 10 ( h - {h}_{x} ) = 10 ( 15 - 5 ) = 100 m \qquad ( 2 )$$

step3. the maximum distance Dₘₐₓ between the two devices can be determined by the following formula. under this distance, the protection range can be enlarged and the lightning protection requirements of the central area can be met, and a certain margin is reserved for the internal area.

$${D}_{max} = 40 ( h - {h}_{x} ) p = 40 ( 15 - 5 ) = 400 m \qquad ( 3 )$$

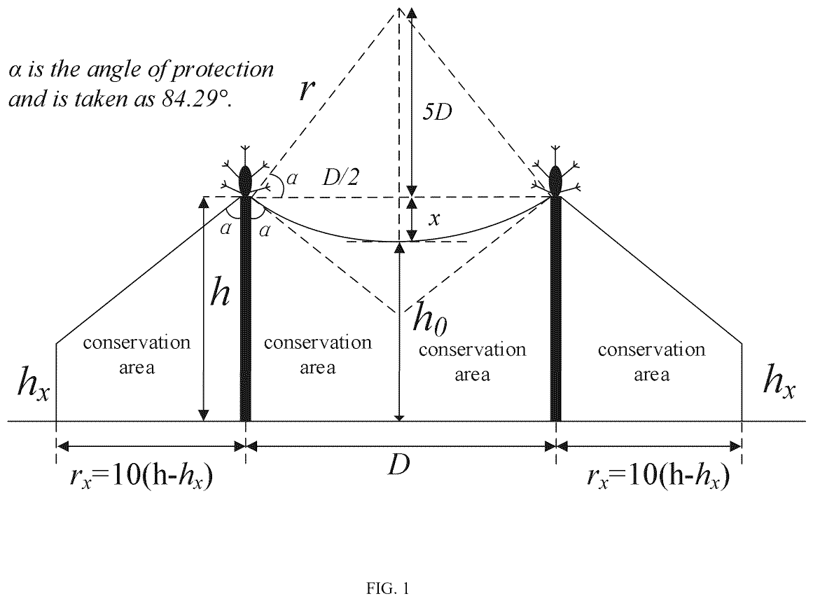

As shown in FIG. 1, it is the protection range of two PLP devices.

As shown in FIG. 2, three PLP devices, namely \textcircled{1}, \textcircled{2} and \textcircled{3} shown in the FIG. 2, are arranged, and the three intersecting circles completely protect the triangle.

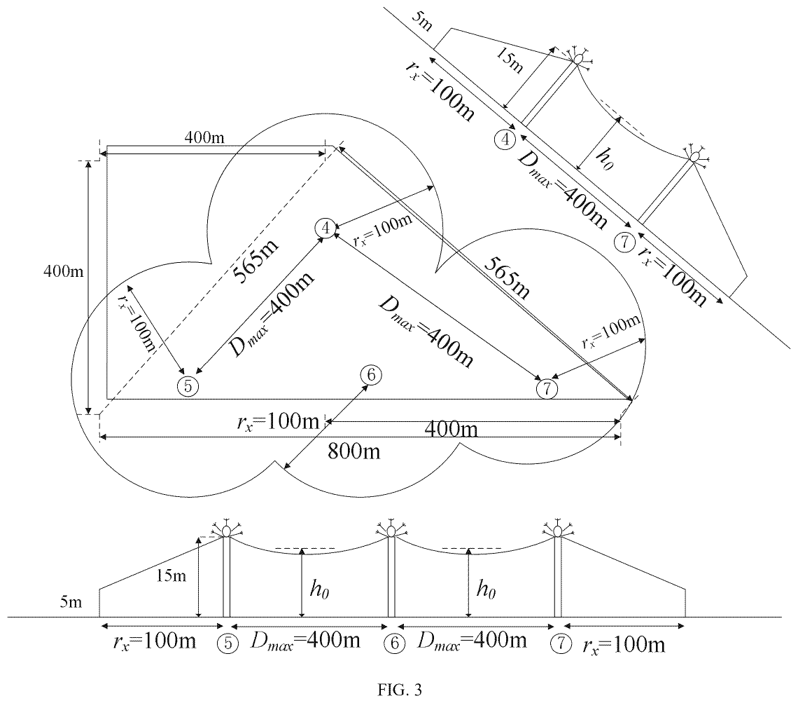

As shown in FIG. 3, the steps for the 2-2′ section are the same as those for the 1-1′ section. Similarly, PLP lightning protection devices can be arranged for the second triangular area. According to the calculation, three PLP devices are also arranged. For the hypotenuse of the triangle whose long side is 800 m, arranging two PLP devices cannot meet the protection requirements. Therefore, one more PLP device is added at the hypotenuse, with a total of four PLP devices, namely \textcircled{4}, \textcircled{5}, \textcircled{6} and \textcircled{7} shown in FIG. 3. The formed protection range can meet the protection requirements of the second triangular area.

### Embodiment 2

In this embodiment, a photovoltaic power station site in an equilateral triangular area with a side length of 900 m is protected. The method includes the following specific steps:
step1. determine the protected height of the photovoltaic panels;

$${h}_{x} = 5 m \qquad ( 1 )$$

step2. giving the initial installation height of PLP as 25 m;
the external protection radius of the PLP device can be determined by the following formula (2):

$${r}_{x} = 10 ( h - {h}_{x} ) = 10 ( 25 - 5 ) = 200 m \qquad ( 2 )$$

step3. the maximum distance Dₘₐₓ between the two devices can be determined by the following formula (3):

$${D}_{max} = 40 ( h - {h}_{x} ) p = 40 ( 25 - 5 ) = 800 m \qquad ( 3 )$$

under this distance, the protection range can be enlarged and the lightning protection requirements of the central area can be met.

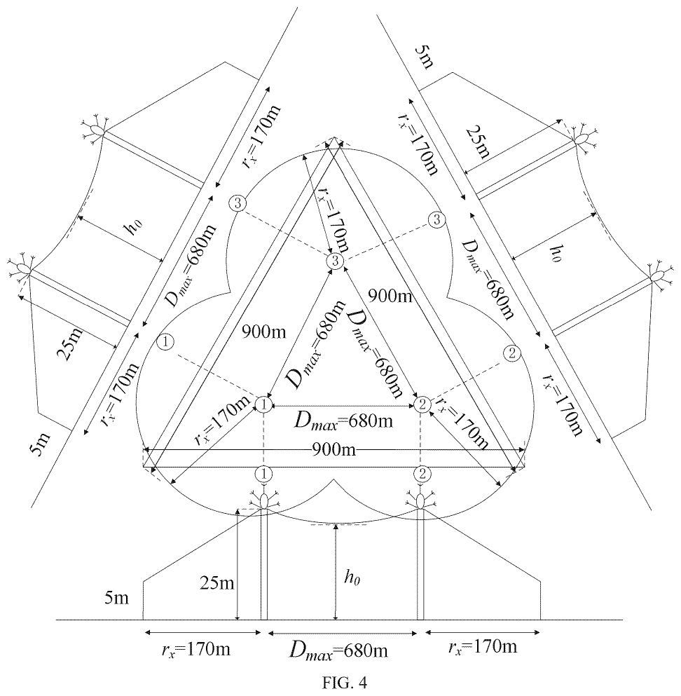

As shown in FIG. 4, a total of 3 PLP devices are set up at the positions marked as \textcircled{1}, \textcircled{2} and \textcircled{3} within the triangular range, and the equilateral triangular area in this embodiment can be completely protected.

### Embodiment 3

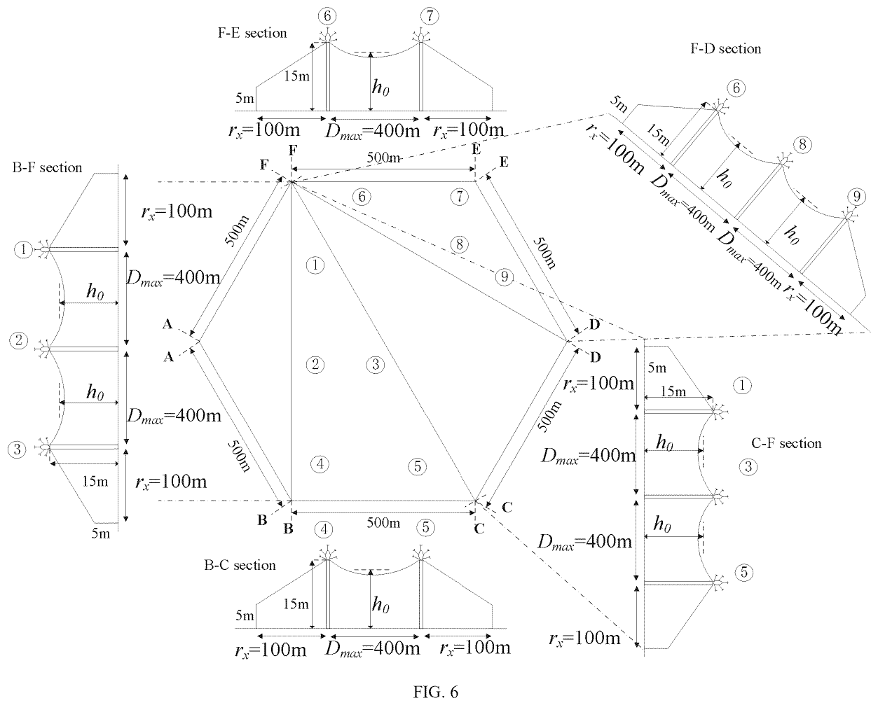

In this embodiment, a photovoltaic power station site in a regular hexagonal area with a side length of 500 m is protected. First, the hexagonal area is divided into four triangular areas. It is easy to know that the two right triangles are congruent, and the two obtuse triangles are also congruent. Therefore, the PLP devices in one right triangle area and one obtuse triangle area can be arranged first, as shown in FIG. 6.

The method described includes the following specific steps:
step1. determine the protected height of the photovoltaic panels;

$${h}_{x} = 5 m \qquad ( 1 )$$

step2. giving the initial installation height of PLP as 15 m;
the external protection radius of the PLP device can be determined by the following formula (2):

$${r}_{x} = 10 ( h - {h}_{x} ) = 10 ( 15 - 5 ) = 100 m \qquad ( 2 )$$

step3. the maximum distance Dₘₐₓ between the two devices can be determined by the following formula:

$${D}_{max} = 40 ( h - {h}_{x} ) p = 40 ( 15 - 5 ) = 400 m \qquad ( 3 )$$

The protection distance of two PLP devices on a straight line is 400+100×2=600 m, and the protection distance of three PLP devices on a straight line is 400×2+100×2=1000 m.

Since the protection range of a single PLP is circular, when the lengths of all sides of the protected area are less than the protection distance of the PLP on a straight line, all the equipment within the protected area will be protected.

As shown in FIG. 6, for the right triangle area, two PLP devices are sufficient for the length of its side of 500 m, three PLP devices are required for the length of the right angle side of 866 m, and three PLP devices are required for the length of the triangle's hypotenuse of 1000 m. A total of five PLP devices are to be installed at points \textcircled{1}\textcircled{2}\textcircled{3}\textcircled{4}\textcircled{5} within the right triangle. For an obtuse triangle, two PLPs are required for the two short sides of 500 meters, and three PLPs are required for the long side of 866 meters. A total of four PLPs are installed at the points \textcircled{6}\textcircled{7}\textcircled{8}\textcircled{9} indicated in the obtuse triangle area.

As shown in FIG. 6, for the right triangle area, two PLP devices can be installed on the side with a length of 500 m, three PLP devices need to be installed on the right-angle side with a length of 866 m, and three PLP devices also need to be installed on the hypotenuse with a length of 1000 m. A total of 5 PLP devices are set up at the positions marked as \textcircled{1}, \textcircled{2}, \textcircled{3}, \textcircled{4} and \textcircled{5} within the right triangle area. For the obtuse triangle area, two PLP devices need to be installed on each of the two short sides with a length of 500 m, and three PLP devices need to be installed on the long side with a length of 866 m. A total of 4 PLP devices are set up at the positions marked as \textcircled{6}, \textcircled{7}, \textcircled{8} and \textcircled{9} within the obtuse triangle area.

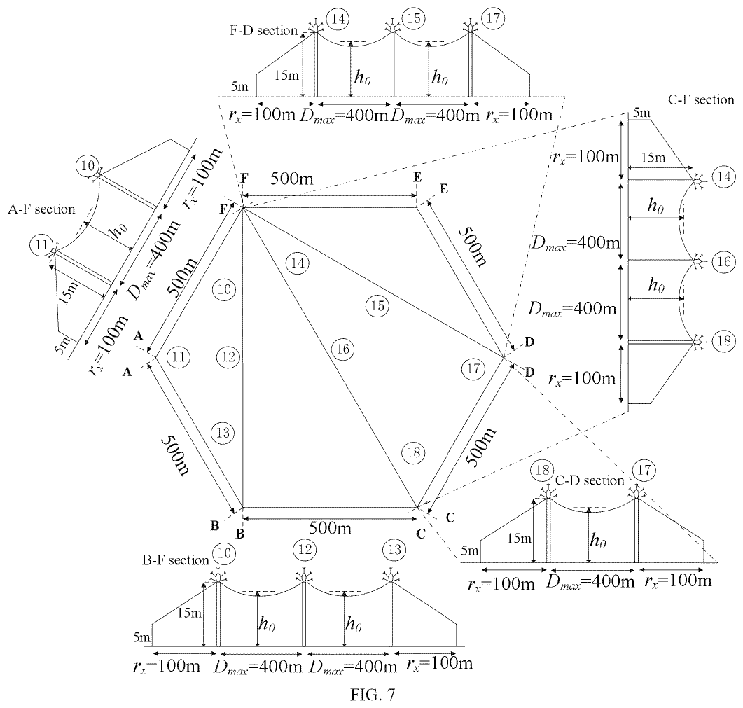

It is easy to know that the layout of the other two triangular areas is exactly the same as that of the above two, as shown in FIG. 7. Therefore, 18 PLP devices can be arranged to completely protect this regular hexagonal area.

The above has described in detail the specific implementation manners of the present invention in combination with the accompanying drawings. However, the present invention is not limited to the above implementation manners. Within the scope of knowledge possessed by those of ordinary skill in the art, various changes can still be made without departing from the purpose of the present invention.

What is claimed is:

1-5. (canceled)

6. An optimization layout method for a Plasma Lightning Protector (PLP) lightning protection in a photovoltaic power station, comprising:
step 1: measuring a range to be protected in a photovoltaic power station site;
step 2: determining a height hₓ of a protected object;
step 3: calculating a protection distance r, of a single PLP device, rₓ=10(h−hₓ), wherein a protection angle of the single PLP device is 84°-86° and a protection radius R=10h, wherein h is an installation height of the single PLP device;
step 4: when the single PLP device does not protect an entire area of the photovoltaic power station site, increasing to two PLP devices, and calculating a lowest protection height h₀ in a middle of the two PLP devices:
$${h}_{0} = h - \frac{D}{40 p}$$
wherein a maximum distance Dₘₐₓ between the two PLP devices with an identical height is to be determined when h₀=hₓ, p is a correction coefficient considering an influence of the installation height of the two PLP devices, and when h≤30 m, p=1; and when 30 m<h≤120 m, p=5.5/\sqrt{h};
step 5: when the two PLP devices still do not meet protection requirements, continuing to increase to three PLP devices, wherein when the three PLP devices form a triangle, a protection range on an outside of the triangle is determined according to a method for the two PLP devices; for the protection range on an inside of the triangle, based on the height hₓ of the protected object, calculating the lowest protection height h₀ of each pair of adjacent PLP devices respectively, and as long as h₀≥hₓ, the protection range on the inside of the triangle meets the protection requirements; and
step 6: when a number of PLP devices continues to increase, dividing the photovoltaic power station site to be protected into two or more triangles, then calculating according to a method for the three PLP devices, referring to the step 3 to the step 5 to calculate the protection range of each of the two or more triangles, and then comprehensively obtaining the protection range of n PLP devices (n>3) until the protection requirements for the protection range of the photovoltaic power station site to be protected are met.

7. The optimization layout method for the PLP lightning protection in the photovoltaic power station according to claim 6, wherein when determining the height hₓ of the protected object in the step 2, when the height hₓ of the protected object is inconsistent and not unique, a maximum height hₓ is taken.

8. The optimization layout method for the PLP lightning protection in the photovoltaic power station according to claim 6, wherein when the protection range rₓ at the height hₓ of the protected object is obtained in the step 3, the installation height h of the single PLP device is less than 30 m.

9. The optimization layout method for the PLP lightning protection in the photovoltaic power station according to claim 6, wherein when determining the maximum distance Dₘₐₓ between two equal-height PLPs in the step 4, a distance
$$\frac{D}{h} \leq 5$$
between the two PLP devices.

10. The optimization layout method for the PLP lightning protection in the photovoltaic power station according to claim 6, wherein a method of increasing an installation height of local PLP devices is adopted to increase the protection range and form an optimal combination of unequal-height PLP groups.
